(19) United States
(12) Patent Application Publication
(10) Pub. No.: US 2013/0027068 A1
(43) Pub. Date: Jan. 31, 2013

(54) APPARATUS AND METHOD FOR TESTING OPERATION PERFORMANCE OF AN ELECTRONIC MODULE UNDER SPECIFIED TEMPERATURE

(71) Applicants: HUNG-DA LI, Taipei (TW); Chun-Yang Chen, Taipei (TW); Chien-Chih Huang, Taipei (TW)

(72) Inventors: HUNG-DA LI, Taipei (TW); Chun-Yang Chen, Taipei (TW); Chien-Chih Huang, Taipei (TW)

(73) Assignee: ATP ELECTRONICS TAIWAN BLVD., TAIPEI (TW)

(21) Appl. No.: 13/218,347

(22) Filed: Aug. 25, 2011

(30) Foreign Application Priority Data
Jul. 29, 2011 (TW) 100126980

(51) Int. Cl. G01R 31/00

(52) U.S. Cl. 324/750.03

(57) ABSTRACT

An apparatus includes a predetermined function circuit board having a primary area for accepting an electronic module to be tested, a secondary area coupled electrically with the primary area, and one cooperation electronic module installed on the secondary area and coupled electrically to the electronic module to define a predetermined function circuit. A thermal insulation device is installed in the primary area and is formed with a thermal insulation chamber for accepting the electronic module and thermally insulating the electronic module from the cooperation electronic module. A thermal control chip is disposed to control a testing temperature of the insulation chamber TIC, thereby providing a testing environment. The electronic module is electrically connected to the apparatus upon the predetermined function circuit performs a predetermined function, thereby carrying out the testing of the operation performance of the tested electronic module within the thermal insulation chamber TIC under a specified temperature.

This application claims the benefits of the Taiwan Patent Application Serial No. 100126980 filed on Jul. 29, 2011, the subject matter of which is incorporated herein by reference.

### BACKGROUND OF THE INVENTION

1. Field of the Invention

The present invention relates to an apparatus and method, more particularly to an apparatus and method, in which a thermal insulation device is implemented in order to provide a testing environment for testing operation performance of an electronic module under a specified temperature.

2. Description of the Prior Art

As far as electronic devices are concerned, more particularly to those having display panel modules, the majority of the electronic devices are provided with system software and application software for carrying out the complicated processing operation. Since the content to be processed becomes more and more complicated and since a shorter time is desired for the processing operation, the operation burden of the late electronic devices becomes large.

Due to large amount of workload, the working temperature of each constituent component in the electronic device grows higher, thereby resulting in several negative performance implications. In order to ensure operation of the electronic device under a high temperature and still maintaining a sufficient performance level, a majority of the electronic modules (constituent components), semi-finished products or finished products are subjected to go for an operation performance testing under the high temperature so as to determine the sufficient operational stability. This is generally known as “Burn-In Test”.

In addition, to be able to complement with low temperature operating environment and specific requirements (low temperature in high latitude area during winter; low temperature operation environment in high altitude areas and in space). The electronic device is still required to operate stably in the low temperature environment. Thus, the electronic modules (constituent components), semi-finished products or finished products, are subjected to go for the operation performance testing under the low temperature environment

As mentioned above, in the prior art, the electronic modules (or constituent components) for undergoing testing operation performance in high or low temperature, a predetermined function circuit board, the electronic module to be tested and an cooperation module are required to carrying out the testing operation. The tested electronic module is installed on the predetermined function circuit board and is further coupled electrically to the cooperation module so as to form a predetermined function circuit.

Afterward, the assembly of the predetermined function circuit board (the cooperation module) and tested electronic module is placed within a test chamber of a constant temperature and humidity control device, where the temperature of the test chamber is adjusted via the compressor, the expansion valve, the condenser, the evaporator and refrigerant constituting a temperature cycling and control system.

To those persons skilled in the art, in the prior art, a relatively large test chamber is required in order to accommodate the assembly consisting of the predetermined function circuit board, the cooperation module and tested electronic module. Further the temperature cycling and control system is needed to adjust the testing temperature of the test chamber, thereby resulting in high electrical expense and a relatively long testing period to maintain the temperature stability within the test chamber. Hence the prior art technique results in serious and costly problem.

### SUMMARY OF THE INVENTION

Since there exist serious and costly problem in the prior art testing technique, the object of the present invention is to provide an apparatus and method for testing an electronic module under a specified temperature, in which, a thermal detection device and a thermal control chip are employed to form a separate thermal insulation chamber and a testing environment for accepting the electronic module thererin, thereby cutting down the electrical power required for testing operation and hence lowering the testing period.

The apparatus of the present invention for testing operation performance of an electronic module under a specified temperature, includes a predetermined function circuit board, a thermal insulation device and a thermal control chip.

The predetermined function circuit board has a primary loading area for accepting the electronic module to be tested, a secondary loading area coupled electrically with the primary loading area, and at least one cooperation electronic module installed on the secondary loading area and coupled electrically to the tested electronic module, thereby defining a predetermined function circuit.

The thermal insulation device is installed in the primary loading area and is formed with a thermal insulation chamber for accepting the tested electronic module therein in order to thermally insulating the tested electronic module with respect to the cooperation electronic module. The thermal control chip is disposed proximate to the thermal insulation chamber in order to control a testing temperature of the thermal insulation chamber, thereby providing a testing environment for the electronic module within the thermal insulation chamber. Upon the predetermined function circuit performs a predetermined function for a certain time interval; the tested electronic module is electrically connected to the apparatus thereby carrying out the testing of the operation-performance of the tested electronic module within the thermal insulation chamber under the specified temperature.

The method provided according to the present invention for testing operation performance of an electronic module under the specified temperature, includes the steps of: (a) preparing a predetermined function circuit board, which has a primary loading area for accepting the electronic module to be tested, a secondary loading area coupled electrically with the primary loading area and at least one cooperation electronic module; (b) installing the cooperation electronic module within the secondary loading area in the predetermined function circuit board; and (c) installing the electronic module within the primary loading area in the predetermined function circuit board and further coupled electrically to the cooperation electronic module, thereby defining a predetermined function circuit.

Afterward, a thermal insulation device is installed within the primary loading area in the predetermined function circuit board. The thermal insulation device is formed with a thermal insulation chamber for accepting the electronic module therein in order to thermally insulating the electronic module with respect to the cooperation electronic module. A thermal control chip is utilized in order to control a testing temperature of the thermal insulation chamber, thereby providing a testing environment for the electronic module to be tested. Upon the predetermined function circuit performs a predetermined function for a certain time interval; the testing of the operation performance of the electronic module is carried out within the thermal insulation chamber under the testing environment and under the specified temperature.

In one embodiment of the present invention, the thermal insulation device preferably includes a thermal insulation base plate and an insulation body. The thermal insulation base plate is sandwiched between the tested electronic module and the predetermined function circuit board and is preferably made from foamed materials. The thermal insulation base plate is formed with a through hole to permit extension of the tested electronic module therethrough for mounting the tested electronic module on the predetermined function circuit board. The insulation body encloses the insulation base plate from above, thereby defining a thermal insulation chamber and hence thermally insulating the tested electronic module with respect to the cooperation electronic module. In addition, the insulation body further includes a partition disposed within the thermal insulation chamber in such a manner to form a thermally adjustable room and an environment operation room below and in spatial communication with the thermally adjustable room. The thermally adjustable room is formed with a recess for accepting a thermal control chip therein in order to control a testing temperature of the thermally adjustable room, thereby providing a testing environment for the electronic module. The environment operation room is to accept the tested electronic module therein.

The testing apparatus of the present invention further includes a thermal detection device, a control unit, a fan unit and a heat dissipation module. The thermal detection device is installed within the thermal insulation chamber in order to generate a thermal sensing signal via the testing temperature of the thermal insulation chamber. The control unit is coupled electrically to the thermal detection device and the thermal control chip in order to adjust the testing temperature via the thermal sensing signal. The fan unit is installed within the thermal insulation chamber so as to provide an air flow in order to uniformly maintaining the testing temperature within the thermal insulation chamber. The heat dissipation module includes a heat dissipating base coupled to the insulated body from above, a plurality of fins projecting outward and upwardly from the heat dissipating base, and an exhaust fan unit mounted proximate to the plurality of fins in order to enhance the air flow within the thermal insulation chamber.

Preferably, the thermal control chip is installed on a wall of the insulation body and is a thermoelectric heating chip, a thermoelectric cooling chip or a thermoelectric heating and cooling chip. A RAM (Random Access Memory) module serves as the electronic module to be tested while the main printed circuit board of the desktop computer serves as the predetermined function circuit board.

In the prior art technique, the predetermined function circuit board (consisting of the cooperation module and tested electronic module) is disposed within a relatively large test chamber of a constant temperature and humidity control device for undergoing the operation performance testing. However, in the present invention, a thermal insulation device and a thermal control chip are employed to form a separate and relatively small thermal insulation chamber and testing environment for accepting the electronic module. So that a considerable large amount of power can be effectively lowered and saved in addition to shortening the testing time owing to uniformly maintaining the testing temperature within the thermal insulation chamber.

As mentioned above, the testing apparatus and method of the present invention can lower cost and expense for testing an operation performance of an electronic module under the specific temperature.

### BRIEF DESCRIPTION OF THE DRAWINGS

Other features and advantages of this invention will become more apparent in the following detailed description of the preferred embodiment of this invention, with reference to the accompanying drawings, in which:

FIG. 1 shows a perspective and exploded view of a preferred embodiment of an apparatus of the present invention for testing operation performance of an electronic module under a specified temperature;

FIG. 2 shows how a thermal insulation base plate is disposed on a predetermined function circuit board to permit extension of an electronic module in the testing apparatus of the present invention;

FIG. 3 shows how an insulation body encloses the insulation base plate shown in FIG. 2 from above in the testing apparatus of the present invention;

FIG. 4 is a cross-sectional view of the testing apparatus of the present invention taken along the lines A-A shown in FIG. 3; and

FIG. 5 is a block diagram illustrating the steps in a method of the present invention for testing operation performance of an electronic module under a specified temperature.

### DETAILED DESCRIPTION OF THE PREFERRED EMBODIMENT

The feature of the present invention resides in an apparatus and method for testing an operation performance of an electronic module under a specified temperature. For better understanding of the present invention, a preferred embodiment is illustrated in the following paragraphs: however, the scope of the invention should not be limited only thereto.

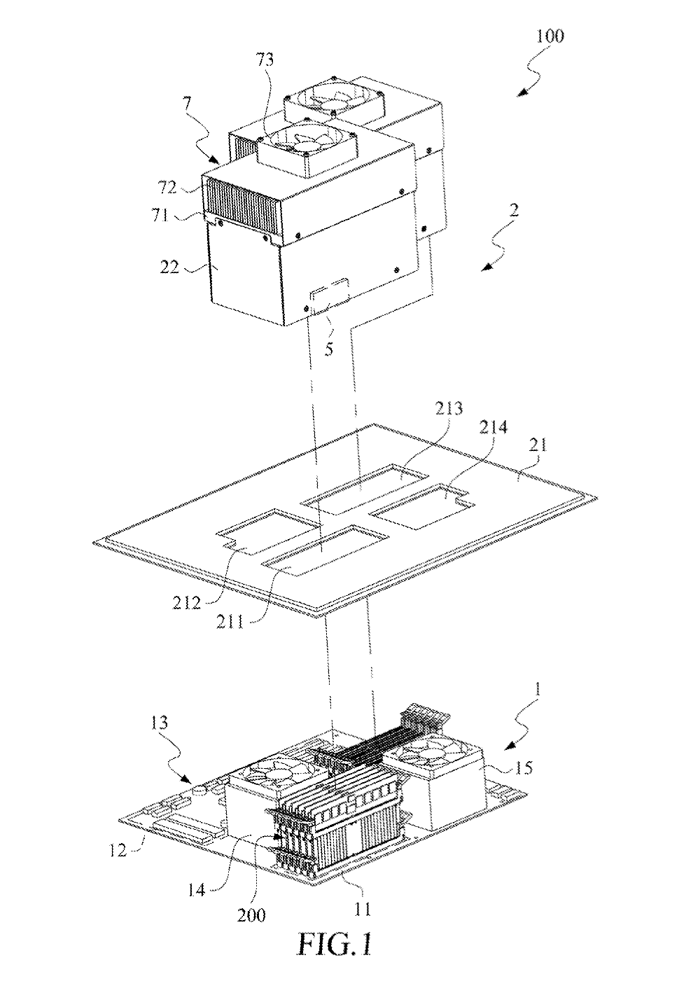

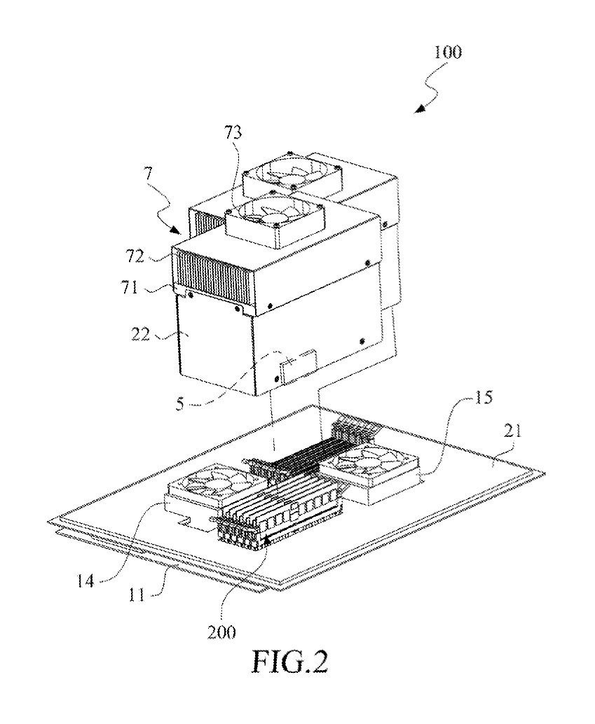

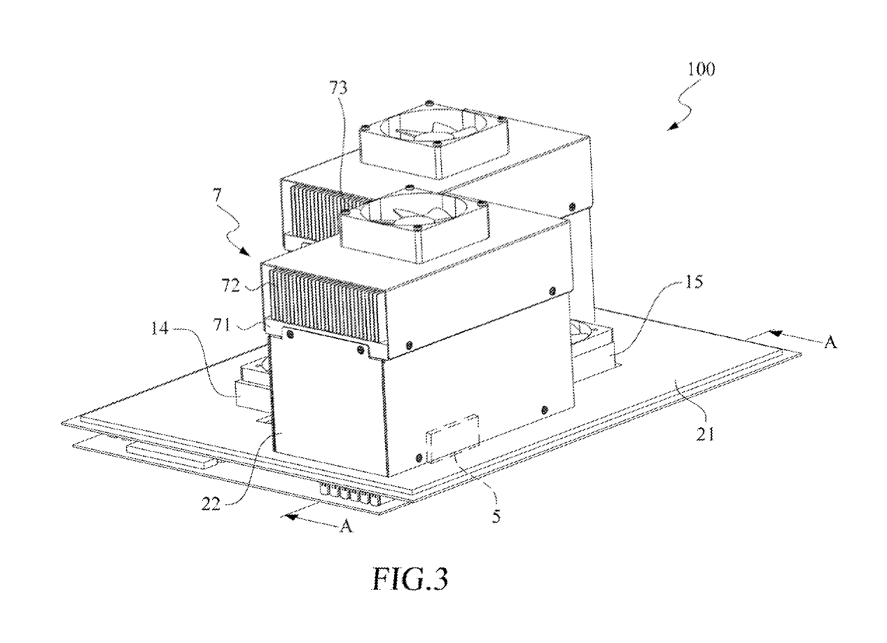

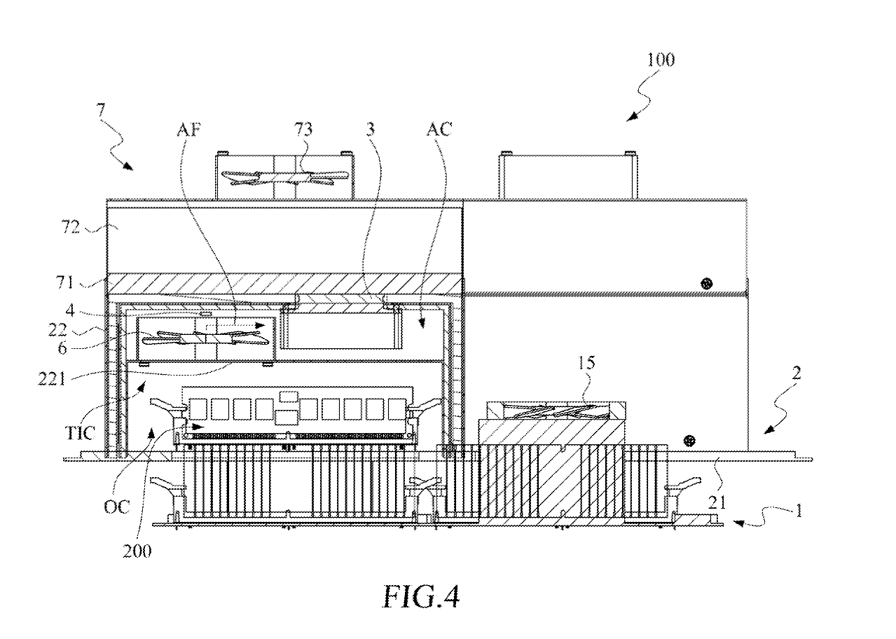

Referring to FIG. 1 and FIG. 4, wherein FIG. 1 shows an exploded perspective view of a preferred embodiment of an apparatus of the present invention for testing an operation performance of an electronic module under a specified temperature; FIG. 2 shows how a thermal insulation base plate is disposed on a predetermined function circuit board to permit extension of an electronic module in the testing apparatus of the present invention; FIG. 3 shows how an insulation body encloses the insulation base plate shown in FIG. 2 from above in the testing apparatus of the present invention; while FIG. 4 is a cross-sectional view of the testing apparatus of the present invention taken along the lines A-A in FIG. 3.

As illustrated, the apparatus 100 of the present invention for testing the operation performance of an electronic module 200 (only one is shown) under the specified temperature, includes a predetermined function circuit board 1, a thermal insulation device 2, a thermal control chip 3, a thermal detection device 4 (see FIG. 4), a control unit 5, a fan unit 6 (see FIG. 4) and at least one heat dissipation module 7 (see FIG. 4).

The function circuit board 1 has a primary loading area 11 for accepting the electronic module 200 to be tested, a secondary loading area 12 coupled electrically with the primary loading area 11, at least one cooperation-electronic module 13 installed on the secondary loading area 12 and coupled electrically to the tested electronic module 200 via a specific connection circuit (not shown), thereby defining a predetermined function circuit, and two circuit fan units 14, 15.

The circuit fan units 14, 15 are connected electrically to the secondary loading area 12 in order to dissipate the heat generated when the predetermined function circuit performs a function.

In this embodiment the predetermined function circuit board 1 is a main printed circuit board of an electronic device, such a top desktop computer a notebook computer, a mobile phone, a flat panel computer set, a PDA (personal digital assistant) or other TV games. The abovementioned electronic module 200 to be tested is a RAM (Random Access Memory) module or other electronic module that can withstand the operation performance testing under high temperature. The predetermined function circuit can be a data read/write circuit a data operation circuit, a power distribution circuit or any other specific function circuit.

For instance, the main printed circuit board of the desktop computer serves as the predetermined function circuit board 1, the RAM (Random Access Memory) module serves as the electronic module 200 to be tested, the data read/write circuit serves as the predetermined function circuit such that the cooperation electronic module 13 is compatible with the RAM module in order to permit operation of the data read/write circuit.

The thermal insulation device 2 preferably includes a thermal insulation base plate 21, and two insulation bodies 22 (only one is shown in FIG. 1). The thermal insulation base plate 21 is sandwiched between the tested electronic module 200 and the predetermined function circuit board 1 and is preferably made from foamed materials. The thermal insulation base plate 21 is formed with four through holes 211, 212, 213, 214, wherein the through hole 211 permits extension of the tested electronic module 200 therethrough for mounting the tested electronic module 200 on the predetermined function circuit board 1, the through hole 212 permits extension of the circuit fan unit 14 for mounting on the predetermined function circuit board 1 while the through holes 213, 214 are intended for other purposes a detailed description thereof is omitted herein for the sake of brevity.

The insulation body 22 encloses the insulation base plate 21 from above, thereby defining a thermal insulation chamber TIC and hence thermally insulating the tested electronic module 200 with respect to the cooperation electronic module 13. In addition, the insulation body 22 further includes a partition 221 disposed within the thermal insulation chamber TIC in such a manner to form a thermally adjustable room AC and an environment operation room OC below and in spatial communication with the thermally adjustable room AC. The thermally adjustable room AC is formed with a recess (not visible) for accepting a thermal control chip 3 therein in order to control a testing temperature of the thermally adjustable room AC, thereby providing a testing environment for the electronic module 200. The environment operation room OC is to accept the tested electronic module 200 therein. In this preferred embodiment the thermal control chip 3 is a thermoelectric heating chip, a thermoelectric cooling chip or a thermoelectric heating and cooling chip.

The thermal detection device 4 is installed within the thermally adjustable room AC (see FIG. 4) or the environment operation room OC. In this embodiment, two thermal detection devices 4 are respectively installed within the thermally adjustable room AC and the environment operation room OC. The control unit 5 is installed on a thermal control circuit plate of the insulation body 22 and is further coupled electrically to the thermal detection devices 4, the thermal control chip 3 and the fan unit 6. The fan unit 6 is installed within the thermally adjustable room AC of the thermal insulation chamber TIC.

The heat dissipation module 7 includes a heat dissipating base 71 coupled to the insulated body 22 from above, a plurality of fins 72 projecting outwardly and upwardly from the heat dissipating base 71, and an exhaust fan unit 73 mounted proximate to the plurality of fins 72 and is further coupled electrically to the control unit 5.

When conducting testing operation performance of the electronic module 200, the temperature of the thermal insulation chamber TIC is adjusted to the testing temperature wherein the thermal detection device 4 generates and transmits a thermal sensing signal to the control unit 5, which in turn, transmits the thermal sensing signal and a fan signal respectively to the thermal control chip 3 and the fan unit 6.

At this time, the thermal control chip 3 adjust the above-stated testing temperature of the thermal insulation chamber TIC via the thermal sensing signal thereby providing a testing environment for the electronic module 200 within the thermal insulation chamber TIC. At the same time, the fan unit 6 is operated due to the fan signal so as to provide an air flow AF in order to uniformly maintaining the testing temperature within the thermal insulation chamber. In addition, the exhaust fan unit 73 of the heat dissipation module 7 is operated due to the control unit 5 so as to enhance the temperature within the thermal insulation chamber TIC. It is to note that the standard testing temperature in the thermal insulation chamber TIC is determined in accordance with the product specifications, and is generally between minus 40t to 85° C.

After determining the testing temperature in the thermal insulation chamber TIC the predetermined function circuit is allowed to perform for a certain time interval such that the tested electronic module 200 is electrically connected to the apparatus 100, thereby carrying out the testing of the operation performance of the tested electronic module 200 within the thermal insulation chamber TIC under the specified temperature. For instance, the RAM module and the read/write circuit of the main circuit board are allow to run continuously for 8 hours in order to conduct the reading/writing operation under the testing environment. Afterward, the RAM module is removed and coupled with the testing apparatus of the present invention (via comparing and matching rate the input data and storage data of the RAM module relative to the output data the RAM module) so as to determine the operation performance of the RAM module under the testing environment (the specific temperature).

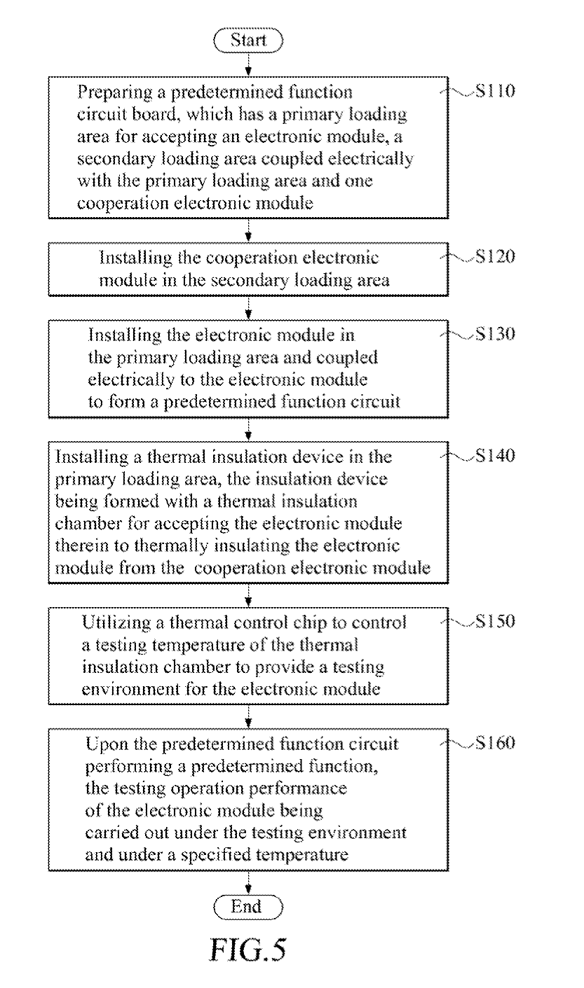

FIG. 5 is a block diagram illustrating the steps in a method of the present invention for testing operation performance of an electronic module under a specified temperature.

As illustrated in FIG. 4 and FIG. 5, the present method is used for testing operation performance of an electronic module 200 under a specified temperature, and includes the following steps.

First of all, a predetermined function circuit board is provided, which has a primary loading area 11, a secondary loading area 12 and at least one cooperation electronic module 13, wherein the secondary loading area 12 is coupled electrically with the primary loading area 11 (Step 110). Afterward, the cooperation electronic module 13 is installed within the secondary loading area 12 in the predetermined function circuit board 1 (Step 120) while the electronic module 200 is installed within the primary loading area 11 in the predetermined function circuit board 1 and is further coupled electrically to the cooperation electronic module 13, thereby defining a predetermined function circuit (Step 130).

The above-mentioned thermal insulation device 2 is installed within the primary loading area 11 in the predetermined function circuit board 1. The thermal insulation device 2 is formed with a thermal insulation chamber TIC for accepting the electronic module 200 therein in order to thermally insulating the electronic module 200 with respect to the cooperation electronic module 13 (Step 140).

A thermal control chip 3 is utilized in order to control a testing temperature of the thermal insulation chamber TIC, thereby providing a testing environment for the electronic module 200 (Step 150).

During adjusting the above-mentioned testing temperature, a thermal detection device 4 is utilized in order to generate a thermal sensing signal in the thermal insulation chamber TIC, after which, a control unit 5 is utilized to control the testing temperature of the thermal insulation chamber TIC via the thermal sensing signal. A fan unit 6 is installed within the thermal insulation chamber TIC so as to provide an air flow AF in order to uniformly maintaining the testing temperature within the thermal insulation chamber TIC.

Finally, upon the predetermined function circuit performs a predetermined function for a certain time interval, the testing of the operation performance of the electronic module 200 is carried out within the thermal insulation chamber TIC under the testing environment (the specified temperature).

In the prior art ones, the predetermined function circuit board (consisting of the cooperation module and tested electronic module) is disposed within a relatively large test chamber of a constant temperature and humidity control device for undergoing the operation performance testing. However, in the present invention, a thermal insulation device 2 and a thermal control chip 3 are employed to form a separate and relatively small thermal insulation chamber and testing environment for accepting the electronic module. So that a considerable large amount of power can be effectively lowered and saved in addition to shortening the testing time owing to uniformly maintaining the testing temperature within the thermal insulation chamber.

As mentioned above, the testing apparatus and method of the present invention can lower cost and expense for testing an operation performance of an electronic module under the specific temperature.

While the invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. An apparatus for testing operation performance of an electronic module under a specified temperature, comprising:
a predetermined function circuit board including
a primary loading area for accepting the electronic module to be tested,
a secondary loading area coupled electrically with said primary loading area, and
at least one cooperation electronic module installed on said secondary loading area and coupled electrically to the tested electronic module, thereby defining a predetermined function circuit;
a thermal insulation device installed in said primary loading area and formed with a thermal insulation chamber for accepting the tested electronic module therein in order to thermally insulating the tested electronic module with respect to said cooperation electronic module; and
a thermal control chip disposed proximate to said thermal insulation chamber in order to control a testing temperature of said thermal insulation chamber, thereby providing a testing environment for the electronic module within said thermal insulation chamber;
wherein, the tested electronic module is electrically connected to the apparatus upon said predetermined function circuit performs a predetermined function, thereby carrying out the testing of the operation performance of the tested electronic module within said thermal insulation chamber under the specified temperature.

2. The apparatus according to claim 1, wherein said thermal control chip is a thermoelectric heating chip, a thermoelectric cooling chip or a thermoelectric heating and cooling chip.

3. The apparatus according to claim 1, further comprising a thermal detection device installed within said thermal insulation chamber in order to generate a thermal sensing signal via said testing temperature of said thermal insulation chamber.

4. The apparatus according to claim 3, further comprising a control unit coupled electrically to said thermal detection device and said thermal control chip in order to adjust said testing temperature via said thermal sensing signal.

5. The apparatus according to claim 1, further comprising a fan unit installed within said thermal insulation chamber so as to provide an air flow in order to uniformly maintaining said testing temperature within said thermal insulation chamber.

6. The apparatus according to claim 1, wherein said thermal insulation device includes
a thermal insulation base plate sandwiched between the tested electronic module and said predetermined function circuit board; and
an insulation body enclosing said insulation base plate from above, thereby defining said thermal insulation chamber and hence thermally insulating the tested electronic module with respect to said cooperation electronic module.

7. The apparatus according to claim 6, wherein said thermal insulation base plate is made from foamed materials.

8. The apparatus according to claim 6, wherein said thermal insulation base plate is formed with a through hole to permit extension of the tested electronic module there through for mounting the tested electronic module on said predetermined function circuit board.

9. The apparatus according to claim 6, wherein said thermal control chip is installed within said insulation body.

10. The apparatus according to claim 6, further comprising a heat dissipation module including
a heat dissipating base coupled to said insulated body from above,
a plurality of fins projecting outward and upwardly from said heat dissipating base, and
an exhaust fan unit mounted proximate to said plurality of fins.

11. The apparatus according to claim 6, wherein said insulation body includes a partition disposed within said thermal insulation chamber in such a manner to form a thermally adjustable room proximate to said thermal control chip and an environment operation room below said thermally adjustable room for accepting the tested electronic module therein.

12. The apparatus according to claim 1, wherein the tested electronic module is a RAM (Random Access Memory) module.

13. The apparatus according to claim 1, wherein said predetermined function circuit board is a main printed circuit board of an electronic apparatus.

14. A method for testing operation performance of an electronic module under a specified temperature, comprising the steps of:
(a) preparing a predetermined function circuit board, which has a primary loading area for accepting the electronic module, a secondary loading area coupled electrically with said primary loading area and at least one cooperation electronic module;
(b) installing said cooperation electronic module within said secondary loading area in said predetermined function circuit board;
(c) installing the electronic module within said primary loading area in said predetermined function circuit board and coupled electrically to said cooperation electronic module, thereby defining a predetermined function circuit;
(d) installing a thermal insulation device within said primary loading area in said predetermined function circuit board, said thermal insulation device being formed with a thermal insulation chamber for accepting the electronic module therein in order to thermally insulating the electronic module with respect to said cooperation electronic module:
(e) utilizing a thermal control chip in order to control a testing temperature of said thermal insulation chamber, thereby providing a testing environment for the electronic module;
(f) upon said predetermined function circuit performing a predetermined function, the testing of the operation performance of the electronic module being carried out within said thermal insulation chamber under said testing environment and under the specified temperature.

15. The method as defined in claim 14, wherein the step (e) further includes a substep (e 1): said testing temperature of said thermal insulation chamber generating a thermal sensing signal.

16. The method as defined in claim 15, wherein the step (e) further includes a substep (e2) after the substep (e1):
adjusting said testing temperature of said thermal insulation chamber via said thermal sensing signal.

17. The method as defined in claim 14, wherein the step (e) further includes a substep (e3): installing a fan unit within said thermal insulation chamber so as to provide an air flow in order to uniformly maintaining said testing temperature within said thermal insulation chamber.

18. The method as defined in claim 14, wherein the electronic module to be tested is a RAM (Random Access Memory) module.

19. The method as defined in claim 14, wherein said predetermined function circuit board is a main printed circuit board of an electronic apparatus.
